(19) United States
(12) Patent Application Publication
(10) Pub. No.: US 2026/0220870 A1
(43) Pub. Date: Jul. 30, 2026

(54) SHADOW RENDERING METHOD AND APPARATUS, DEVICE, AND MEDIUM

(71) Applicant: Beijing Zitiao Network Technology Co., Ltd., Beijing (CN)

(72) Inventors: Qi YUAN, Beijing (CN); Mingzhen ZHANG, Beijing (CN)

(21) Appl. No.: 19/145,886

(22) PCT Filed: Dec. 12, 2023
(86) PCT No.: PCT/CN2023/138091

§ 371 Date: Jul. 3, 2025

(30) Foreign Application Priority Data
Jan. 6, 2023 (CN) 202310020861.5

(51) Int. Cl. G06T 15/04; G06T 15/60; G06T 19/00

(52) U.S. Cl. CPC G06T 15/04; G06T 15/60; G06T 19/006

(57) ABSTRACT

The present disclosure discloses a shadow rendering method and apparatus, a device, and a medium. A simulation model corresponding to a target part is acquired, and includes a plurality of vertices. The target part refers to a part where a try-on object is mounted. Texture unwrapping is performed on the simulation model to obtain a texture map. A shadow corresponding to the try-on object is acquired, the shadow is baked onto the texture map to obtain a shadow map, and shadow rendering is performed on the simulation model according to the vertices in the simulation model and the shadow map to obtain a try-on model.

### CROSS-REFERENCE TO RELATED APPLICATION(S)

This application is a U.S. National Stage Application of PCT Application Serial No. PCT/CN2023/138091, filed on Dec. 12, 2023, which claims priority to Chinese Inventive patent application No. 202310020861.5, entitled “SHADOW RENDERING METHOD AND APPARATUS, DEVICE, AND MEDIUM”, and filed on Jan. 6, 2023, the disclosures of which are incorporated by reference in their entireties.

### FIELD

The present disclosure relates to the field of computer technology, and specifically, to a shadow rendering method and apparatus, a device, and a medium.

### BACKGROUND

With the continuous development of augmented reality (AR) technology, an increasing number of enterprises are utilizing computers and other science and technology to simulate and superimpose physical information (visual information, sound, taste, touch, etc.) that is difficult to experience within a certain time and space range in the real world. This application of virtual information to the real world causes the virtual information to be perceived by human senses, thereby achieving a sensory experience that transcends reality. AR virtual try-on is becoming increasingly popular, enabling users to carry out try-on without leaving their homes and simulating real wearing effects.

### SUMMARY

In view of this, the present disclosure provides a shadow rendering method and apparatus, a device, and a medium, so as to improve a shadow rendering effect while reducing performance consumption.

In order to achieve the above objectives, the present disclosure provides the following technical solutions:

In a first aspect, the present disclosure provides a shadow rendering method. The method includes:
acquiring a simulation model corresponding to a target part, where the simulation model includes a plurality of vertices, and the target part refers to a part where a try-on object is mounted;
performing texture unwrapping on the simulation model to obtain a texture map;
acquiring a shadow corresponding to the try-on object;
baking the shadow onto the texture map to obtain a shadow map; and
rendering the simulation model according to the vertices in the simulation model and the shadow map to obtain a try-on model.

In a second aspect, the present disclosure provides a shadow rendering apparatus. The apparatus includes:
an acquiring unit, configured to acquire a simulation model corresponding to a target part, where the simulation model includes a plurality of vertices, and the target part refers to a part where a try-on object is mounted;
an unwrapping unit, configured to perform texture unwrapping on the simulation model to obtain a texture map,
where the acquiring unit is further configured to acquire a shadow corresponding to the try-on object; and
a bake unit, configured to bake the shadow onto the texture map to obtain a shadow map,
where the acquiring unit is further configured to render the simulation model according to the vertices in the simulation model and the shadow map to obtain a try-on model.

In a third aspect, the present disclosure provides an electronic device. The device includes a processor and a memory;
the memory is configured to store instruction or a computer program; and
the processor is configured to execute the instructions or the computer program in the memory to cause the electronic device to perform the method in the first aspect.

In a fourth aspect, the present disclosure provides a computer-readable storage medium, having instructions stored therein. The instructions, when running on a device, cause the device to perform the method in the first aspect.

In a fifth aspect, the present disclosure provides a computer program product. The computer program product includes a computer program/instruction. The computer program/instruction, when executed by a processor, implements the method in the first aspect.

### BRIEF DESCRIPTION OF THE DRAWINGS

In order to describe technical solutions in embodiments of the present disclosure or in the prior art more clearly, the accompanying drawings required to be used in descriptions of the embodiments or the prior art will be briefly introduced below, it is apparent that the accompanying drawings described below are merely some embodiments recorded in the present disclosure, and those of ordinary skill in the art can obtain other accompanying drawings according to these accompanying drawings without creative work.

FIG. 1 is a flowchart of a shadow rendering method according to an embodiment of the present disclosure;

FIG. 2a is a schematic diagram of a wrist simulation model according to an embodiment of the present disclosure;

FIG. 2b is a schematic diagram of a human head simulation model according to an embodiment of the present disclosure;

FIG. 2c is a schematic diagram of texture unwrapping of a wrist simulation model according to an embodiment of the present disclosure;

FIG. 2d is a schematic diagram of texture unwrapping of a human head simulation model according to an embodiment of the present disclosure;

FIG. 3a is a schematic diagram of acquiring a shadow using a camera device according to an embodiment of the present disclosure;

FIG. 3b is a schematic diagram of excessive rendering according to an embodiment of the present disclosure;

FIG. 3c is a schematic diagram of additionally adding vertices according to an embodiment of the present disclosure;

FIG. 4a is a diagram of a watch try-on effect according to an embodiment of the present disclosure;

FIG. 4b is a diagram of another watch try-on effect according to an embodiment of the present disclosure;

FIG. 4c is a schematic diagram of a segmentation mask according to an embodiment of the present disclosure;

FIG. 5 is a structural diagram of a shadow rendering apparatus according to an embodiment of the present disclosure; and

FIG. 6 is a schematic diagram of a structure of an electronic device according to an embodiment of the present disclosure.

### DETAILED DESCRIPTION OF EMBODIMENTS

In order to make those skilled in the art better understand solutions of the present disclosure, the technical solutions in the embodiments of the present disclosure are clearly and completely described with reference to the accompanying drawings in the embodiments of the present disclosure as below, and it is apparent that the described embodiments are merely a part rather all embodiments of the present disclosure. Based on the embodiments of the present disclosure, all other embodiments obtained by those of ordinary skill in art without creative work shall fall within the scope of protection of the present disclosure.

In AR virtual try-on, lighting consistency is often regarded as a crucial indicator for virtual-real fusion. Lighting consistency refers to ensuring that virtual objects have the same lighting effects as real objects. The goal of the lighting consistency is to align the lighting conditions of the virtual objects with those of the real scenario, meaning that the virtual objects and the real objects share consistent lighting and shadow effects, thereby enhancing the realism of the virtual objects. Currently, to achieve AR shadow drawing, shadow calculations are primarily performed based on real-time lighting. The calculation method consumes significant performance, affecting rendering efficiency. Currently, there are mainly following two methods used to achieve shadow rendering in AR try-on:

One method involves real-time shadow calculation according to lighting. Since the realism of AR needs to be determined according to parameters such as a light source position, direction, and intensity, a better shadow effect can be obtained through real-time calculation. However, for mobile terminals or Web browser terminals, the real-time calculation demands significant performance.

The other method involves fake shadows, which can create shadows for try-on objects without lighting. Specifically, in digital content creation (DCC) software, a shadow may be baked onto a mesh in advance, where the mesh resembles the shape of a mounting part. However, the baked shadow on the mesh cannot adapt to the changes of the mounting part, resulting in a poor fit effect of the shadow, and as a result, the shadow hovers above the mounting part rather than on the mounting part.

Based on this, the present disclosure provides a shadow rendering method. Specifically, a simulation model corresponding to a target part is acquired, which includes a plurality of vertices. Texture unwrapping is performed on the simulation model to obtain a texture map corresponding to the simulation model. A shadow corresponding to a try-on object is acquired, and the shadow corresponding to the try-on object may be pre-generated or acquired using a camera device. That is, the shadow in the present disclosure is pre-generated or acquired using the camera device, without the need for the real-time calculation according to lighting, thereby reducing performance consumption. Moreover, after the shadow of the try-on object is acquired, the shadow is baked onto the texture map to obtain a shadow map, and the simulation model is rendered according to the shadow map and the vertices in the simulation model to obtain a try-on model. In other words, according to the present disclosure, the shadow is baked onto the texture map corresponding to the simulation model. When the target part changes, the texture map of the corresponding simulation model changes as well, such that the baked shadow adapts to the changes of the target object, thereby improving a rendering effect.

It should be understood that before the use of the technical solutions of the embodiments of the present disclosure, a user shall be informed of the type, range of use, use scenarios, etc., of involved personal information in an appropriate manner in accordance with relevant laws and regulations, and the authorization of the user shall be obtained.

For example, in response to the reception of an active request from the user, a prompt message is sent to the user to clearly indicate to the user that it is necessary to obtain and use the personal information of the user for the operation requested to be performed. Therefore, the user may freely select, according to the prompt message, whether to provide the personal information for software or hardware such as an electronic device, an application, a server, or a storage medium executing the operations of the technical solutions of the present disclosure.

As an optional but non-limiting implementation, in response to the reception of the active request from the user, the prompt message may be sent to the user in the form of, for example, a pop-up window, in which the prompt message may be presented in text. Further, the pop-up window may also carry a selection control for the user to choose whether to “agree” or “disagree” to provide the personal information to the electronic device.

It should be understood that the above notification and user authorization obtaining process is only illustrative, which does not limit the implementations of the present disclosure, and other methods that comply with the relevant laws and regulations may also be applied to the implementations of the present disclosure.

To facilitate the understanding of the technical solutions provided in the present disclosure, the description is made below with reference to the accompanying drawings.

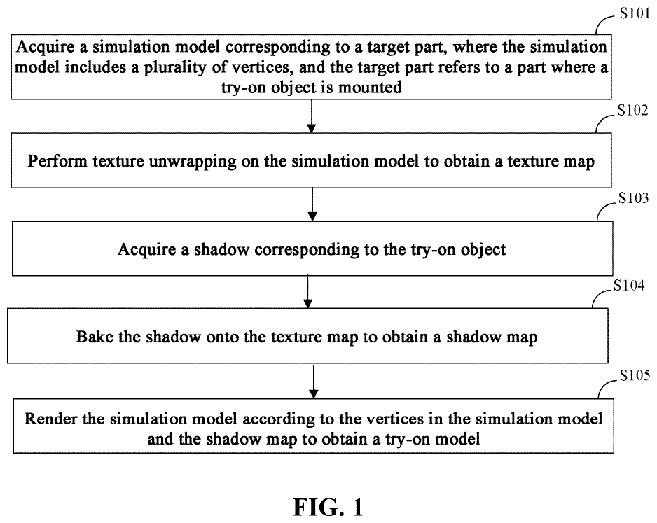

Referring to FIG. 1, the figure is a flowchart of a shadow rendering method according to an embodiment of the present disclosure. As shown in FIG. 1, the method may be performed by a shadow rendering client, and the shadow rendering client may be deployed in an electronic device. The electronic device may include a mobile phone, a tablet computer, a notebook computer, a desktop computer, a vehicle terminal, a wearable electronic device, an all-in-one machine, a smart home device, and other devices with a communication function, or may also be a device simulated by a virtual machine or an emulator. As shown in FIG. 1, the method may include the following steps.

S101: A simulation model corresponding to a target part is acquired.

In this embodiment, to achieve AR try-on rendering, the simulation model corresponding to the target part is first acquired. The target part refers to a part where a try-on object is mounted, and different try-on objects correspond to different mounting parts. For example, the try-on object may be an item such as a watch, a ring, a necklace, and earrings, and the target part may include a part such as the wrist, the finger, the neck, and the head.

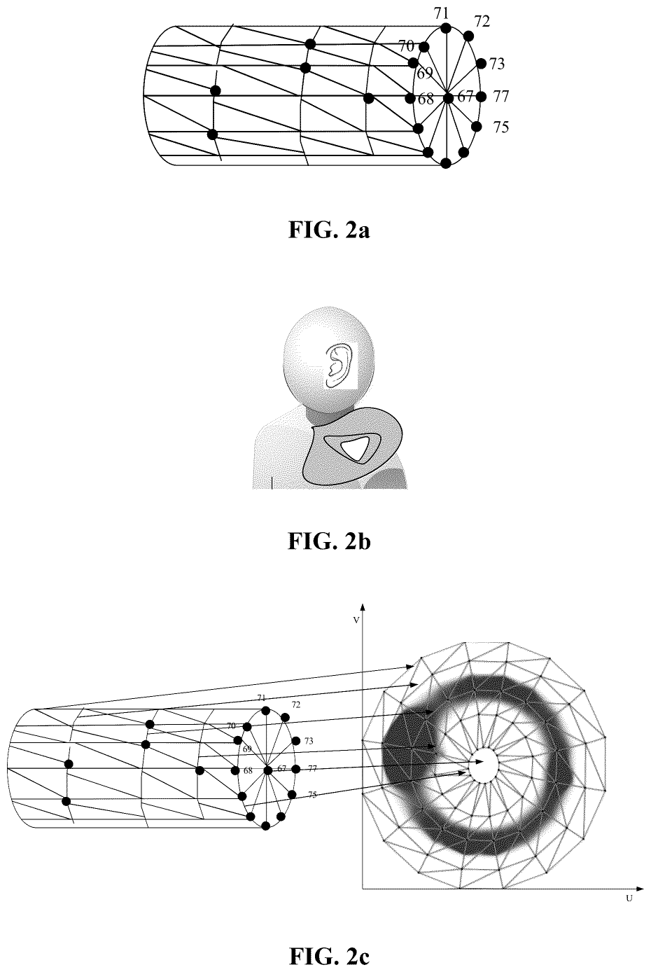

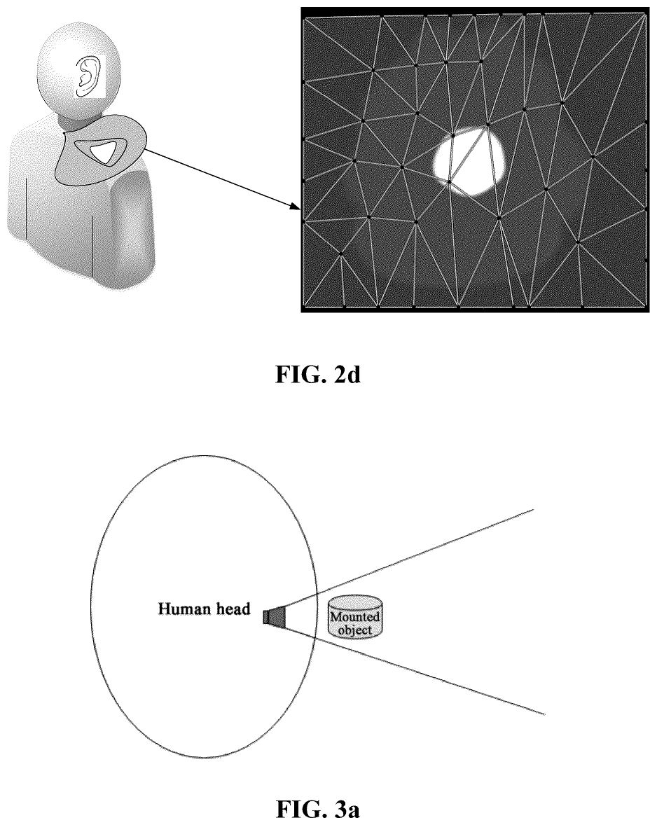

A plurality of vertices may be marked on the simulation model, and the simulation model is formed by connecting the vertices. For example, as shown in FIG. 2a, taking the watch as a mounted object and the wrist as the target part, the simulation model corresponding to the wrist is a cylinder, which includes a plurality of vertices, and each vertex is marked with a sequence number. For another example, a simulation model corresponding to the head is shown in FIG. 2b when the mounted object is the earring and the target part is the head, various vertices are not shown in the simulation model.

S102: Texture unwrapping is performed on the simulation model to obtain a texture map and a texture coordinate value corresponding to each of the plurality of vertices.

After the simulation model of the target part is acquired, texture unwrapping is performed on the simulation model to obtain the texture map. Various points on the texture map are in one-to-one correspondence with the vertices on the simulation model, and therefore the texture coordinate value corresponding to at least one vertex on the simulation model may also be obtained through the texture map. The texture coordinate value refers to a UV coordinate value, where U indicates a horizontal direction, and V indicates a vertical direction. Performing texture unwrapping on the simulation model refers to mapping a three-dimensional model to a two-dimensional plane.

To ensure that after performing texture unwrapping on the simulation model, each vertex on the simulation model has a corresponding texture coordinate value, texture unwrapping is performed on the simulation model according to a preset unwrapping rule to obtain the texture map. The preset unwrapping rule refers to determining that a topological form in the texture map is kept consistent with a topological form in the simulation model without disrupting the vertices and connection lines in the simulation model.

For example, referring to FIG. 2c, texture unwrapping is performed in an application scenario shown in FIG. 2a, the left side shows the simulation model, and the right side shows the texture map. A leftmost part of the simulation model corresponds to an outermost layer line in the texture map after texture unwrapping, and a rightmost part of the simulation model corresponds to an innermost layer line in the texture map after texture unwrapping. Further, the connection lines on the texture map are in one-to-one correspondence with the connection lines on the simulation model, and intersection points of the connection lines on the texture map are in one-to-one correspondence with the vertices on the simulation model.

Additionally, when texture unwrapping is performed on the simulation model, the simulation model may be completely or partially unfolded according to an area where the try-on object is about to cast a shadow. For example, texture unwrapping is performed on the simulation model in FIG. 2c. When the try-on object only casts the shadow in a partial area of the simulation model, texture unwrapping may be only performed on the partial area. For example, as shown in FIG. 2d, taking the AR earring try-on as an example, the earring will be mounted near an earlobe of a human head model. The shadow of the earring is commonly cast to a partial area below the ear. Therefore, it is only necessary to perform texture unwrapping on a part of mesh vertices below the ear, while texture coordinate values of the remaining mesh vertices may be uniformly set to texture coordinate values corresponding to a transparent part on the shadow map.

S103: A shadow corresponding to the try-on object is acquired.

The shadow corresponding to the try-on object may be pre-generated or acquired in real time using a camera device. Specifically, if the try-on object is stationary relative to the target part, a shadow corresponding to the try-on object is pre-generated. Relatively stationary refers to situations where the form, the mounting position, etc. of the mounted object do not significantly change in the AR try-on process, such as a watch being worn on the wrist in a fixed position without rotation, or a ring being worn on a finger all the time. If the try-on object moves relative to the target part, a shadow corresponding to the try-on object is drawn using an initial shadow acquired by the camera device. Relative movement refers to situations where the form, the mounting position, etc. of the mounted object significantly change in the AR try-on process, such as a necklace swinging due to a physical effect or the earring swaying on the ear.

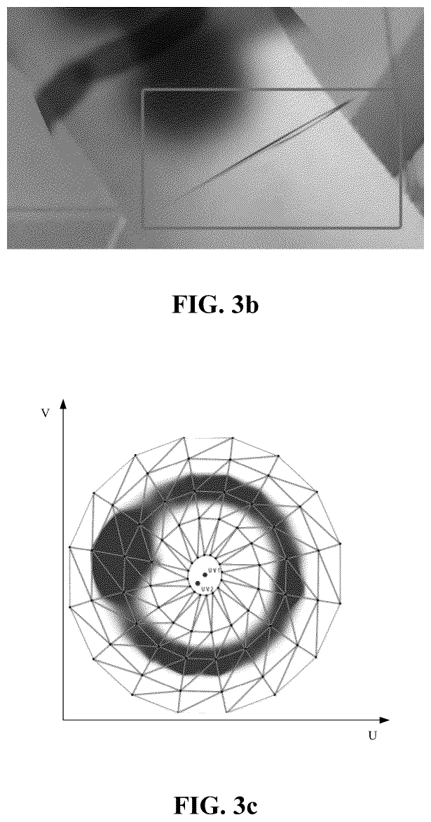

In some implementations, when the camera device is used to acquire the shadow of the try-on object, the position and orientation of the camera device satisfy the following conditions: when the try-on object moves towards the target part, the shadow of the try-on object conforms to a relationship of being smaller at a distance and larger closer. For example, FIG. 3a shows a positional relationship between the try-on object, the human head model, and a camera.

Specifically, when the camera device is used to acquire the shadow corresponding to the try-on object, the initial shadow corresponding to the try-on object is first acquired using the camera device; and a shadow corresponding to the try-on object is drawn according to the initial shadow. In other words, an image of the try-on object is acquired using the camera device, and then the shadow corresponding to the try-on object is drawn according to the acquired image. Specifically, the shadow of the try-on object is drawn according to an alpha channel of the camera device when acquiring the image of the try-on object and an adjustable parameter (Translucency) that additionally controls shadow transparency, where the alpha channel refers to a channel on RT1, that is, an area of the mounted object on the image may be obtained through an opaque area. An image of the mounted object on RT1 is obtained by rendering the mounted object from a side surface using the camera device, where alpha>0 indicates the area where the mounted object is present, and alpha=0 indicates the area where no mounted object is present. That is, through the above method, the image area corresponding to the mounted object on RT1 may be drawn onto RT2.

In some implementations, after obtaining the shadow corresponding to the try-on object, in order to enhance the realism of the shadow and achieve an effect of a soft shadow with a smooth edge, specifically, Gaussian blur processing is performed on the shadow of the try-on object, to obtain a processed shadow. The Gaussian blur processing, also known as Gaussian smoothing, is an image blur filter processing effect widely used in image processing software, and is commonly employed to achieve an edge feathering effect. That is, the Gaussian blur processing is performed on the shadow on RT2 to obtain an edge feathering effect similar to that of the soft shadow. The edge feathering may be understood as virtualizing an edge part.

Typically, when the try-on object is closer to a projection surface, the color of the projection should be darker (less transparent), and the edge feathering should be smaller (less blur). Therefore, it is necessary to dynamically modify shadow transparency and blur intensity according to a distance between the try-on object and the mounting position.

Specifically, the shadow transparency may be modified through a clamp function, an alpha channel value, maximum transparency max_alpha, and the distance dist between the try-on object and the mounting position, where the clamp function normalizes the value to the range from 0 to 1. The blur intensity may be modified through the maximum transparency max_alpha, and the distance dist between the try-on object and the mounting position.

S104: The shadow onto the texture map to obtain a shadow map is baked.

After acquiring the shadow of the try-on object, the shadow is baked onto the texture map to obtain the shadow map. For example, in the right image in FIG. 2c, the shadow of the watch is drawn onto the texture map to obtain the shadow map.

In some implementations, if Gaussian blur processing is performed on the shadow of the try-on object before baking, the processed shadow is baked onto the texture map to obtain the shadow map.

S105: The simulation model is rendered according to the vertices in the simulation model and the shadow map to obtain a try-on model.

After obtaining the shadow map, the simulation model is rendered according to the vertices in the simulation model and the shadow map to obtain the try-on model, thereby ensuring that the shadow of the try-on object on the try-on model can fit onto the target part, and improving a rendering effect. Since the vertices in the simulation model correspond to the vertices on the texture map, rendering may be performed according to a correspondence between the vertices in the simulation model and the vertices on the shadow map to obtain the try-on model.

In some implementations, after obtaining the texture map, the texture coordinate value corresponding to at least one vertex in the simulation model may be obtained through the texture map, and therefore the simulation model may be rendered according to the texture coordinate value corresponding to the at least one vertex in the simulation model and the shadow map to obtain the try-on model.

In the present disclosure, the simulation model corresponding to the target part is acquired, which includes the plurality of vertices. The target part refers to the part where the try-on object is mounted. Texture unwrapping is performed on the simulation model to obtain the texture map. The shadow corresponding to the try-on object is acquired, and the shadow corresponding to the try-on object may be pre-generated or acquired using the camera device, without the need for the shadow calculation according to real-time lighting, thereby reducing resource occupation. The shadow is baked onto the texture map to obtain the shadow map, and then shadow rendering is performed on the simulation model according to the vertices in the simulation model and the shadow map to obtain the try-on model. In other words, according to the present disclosure, during shadow baking, the shadow is baked onto the texture map corresponding to the simulation model after texture unwrapping, rather than onto a planar model similar to the target part, thereby making shadow rendering more closely fitted, and improving the rendering effect.

In some implementations, the simulation model may be rendered to obtain the try-on model through the following method, specifically: the shadow map is sampled according to a texture coordinate value corresponding to at least one vertex in the simulation model to obtain a sampling result; and shadow rendering is performed on the simulation model according to the sampling result to obtain a try-on model. In other words, a shader may sample a shadow pixel value corresponding to the texture coordinate value from the shadow map according to the texture coordinate values corresponding to respective vertices in the simulation model, and then rendering is performed on the simulation model according to the shadow pixel value.

In some implementations, before acquiring the sampling result, the texture coordinate values corresponding to the vertices are exported from the texture map according to an order of the vertices in the simulation model, and then sampling is performed according to the export order of the texture coordinate values.

In some implementations, when texture unwrapping is performed and the simulation model is a cylinder, in order to avoid excessive textures on a circular surface of the simulation model during rendering (the circular surface should originally be transparent without any texture), for example, as shown in FIG. 3b, the position circled by a box in the figure should not have any shadow rendered and should be transparent. However, during sampling, the sampling process from the “vertices on a lateral ring (a test ring adjacent to the innermost ring)” to the “vertices of the innermost ring” as shown in the right image of FIG. 2c, interpolation may be performed, which may cause the circular surface to be rendered with incorrect and excessive textures. Therefore, an additional ring of vertices needs to be added near the adjacent circular surface (the innermost ring). As shown in FIG. 3c, the texture coordinates UV1 represent the vertices of the innermost ring, while the texture coordinates UV2 represent the additionally added vertices. The texture coordinate values of the additionally added ring of vertices satisfy the following conditions:
(1) ensuring that after linear interpolation between UV1 and UV2, the texture colors corresponding to generated other texture coordinate values are transparent; and
(2) ensuring that after linear interpolation between UV1 and the respective texture coordinate values of a ring of vertices on the circular surface, the texture colors corresponding to generated other texture coordinate values are transparent as well.

Additionally, to avoid stretching of the sampled texture shape, the texture coordinates may be scaled and offset during texture sampling. Specifically, the texture coordinates may be multiplied by a scaling factor Tiling and then added with an offset value offset to achieve scaling and offsetting of the texture coordinates. Both tiling and offset are two-dimensional vectors (x, y), corresponding to the scaling factor and the offset value in an x direction and a y direction respectively.

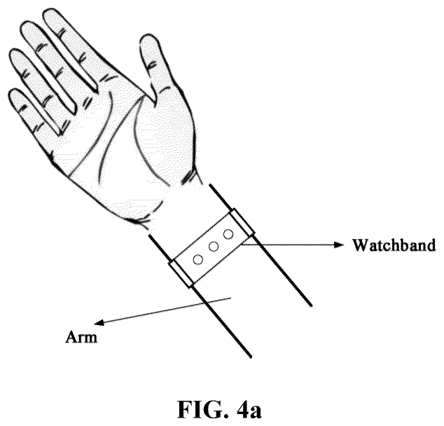

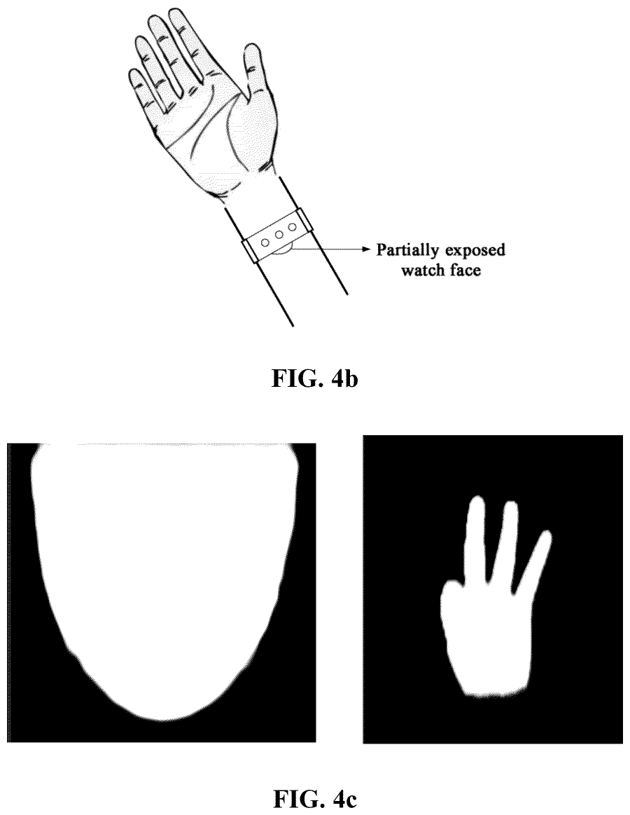

In some implementations, after obtaining the try-on model, in response to the user using the try-on model, rendering is performed on the target part of the user according to the try-on model. For example, as shown in FIG. 4a, when the try-on model indicates that the user tries on a watch and performs try-on through a try-on client, the watch and a corresponding shadow of the watch are rendered on the wrist of the user.

When the try-on object encircles the target part, during rendering on the target part of the user according to the try-on model, rendering needs to be performed on the target part of the user according to the try-on model and the processed simulation model. The processed simulation model is opaque and is used to obscure a partial area of the try-on object.

Typically, a material of the simulation model for shadow rendering should be set to be transparent, such that a try-on effect can be normally displayed with the shadow map and the texture map on the simulation model, and non-shadow map parts appearing transparent. However, a transparent simulation model may fail to correctly obscure the try-on object. For example, as shown in FIG. 4b, the transparent simulation model fails to correctly obscure the watch, revealing parts that should not be displayed, such as a partially exposed watch face shown in FIG. 4b. Based on this, a simulation model without shadow mapping needs to be additionally added to the scenario to correctly obscure the try-on object, a material of the simulation model is set to be opaque, a depth of the simulation model is written, but a color is not written. The depth of the simulation model refers to a distance between each vertex on the model and the camera. Objects that are closer to the camera along the same line definitely obscure those that are farther away. By writing the depth, relative positional relationships between the objects can be compared. For example, if the depth of an obscuring object is closer to the camera than that of an object A, the object A will not be rendered, resulting in an effect of being obscured. Further, the scale of the simulation model with shadow mapping may also be set to 1.001 times, thereby preventing overlapping with the simulation model for obscuring. The effect after adding the obscuring simulation model is shown in FIG. 4a, and the effect meets expectations correctly.

In some implementations, due to potential deviations between the vertices returned by the simulation model and an actual mounted object (the wrist, the human head, etc.), a segmentation method is used again after obtaining the try-on model to more precisely control a shadow area, thereby removing an excessive part. Specifically, a grayscale map corresponding to the target part is obtained; and according to the grayscale map, the shadow area corresponding to the try-on model is segmented to remove an excessive shadow area in the try-on model. The excessive shadow area refers to other shadow area(s) except the shadow area corresponding to the target part within the shadow area corresponding to the try-on model. Specifically, a segmentation mask may be used for segmentation. When the mask is 0, no rendering is required; and when the mask is greater than 0, rendering is required. Through the segmentation mask, a grayscale map that represents areas such as the face and the hand may be obtained through a face segmentation algorithm, a hand segmentation algorithm, etc. For example, as shown in FIG. 4c, the white parts represent areas such as the face and the hand, and the black parts represent the areas that need to be removed.

Based on the above method embodiments, an embodiment of the present disclosure provides a shadow rendering apparatus and an electronic device, which are described with reference to the accompanying drawings as below.

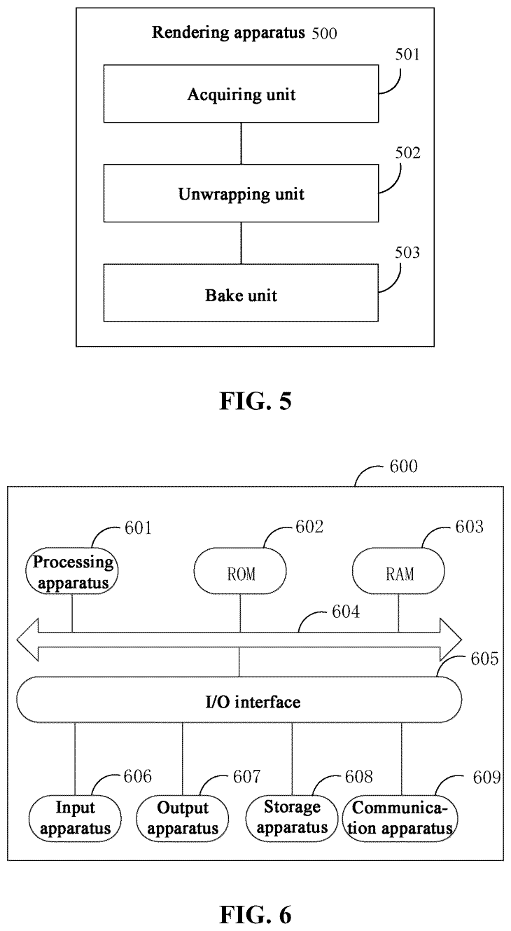

Referring to FIG. 5, the figure is a structural diagram of a shadow rendering apparatus according to an embodiment of the present disclosure. As shown in FIG. 5, the apparatus 500 may include: an acquiring unit 501, an unwrapping unit 502, and a bake unit 503.

The acquiring unit 501 is configured to acquire a simulation model corresponding to a target part. The simulation model includes a plurality of vertices, and the target part refers to a part where a try-on object is mounted.

The unwrapping unit 502 is configured to perform texture unwrapping on the simulation model to obtain a texture map.

The acquiring unit 501 is further configured to acquire a shadow corresponding to the try-on object.

The bake unit 503 is configured to bake the shadow onto the texture map to obtain a shadow map.

The acquiring unit 501 is further configured to render the simulation model according to the vertices in the simulation model and the shadow map to obtain a try-on model.

In some implementations, the acquiring unit 501 is further configured to acquire a texture coordinate value corresponding to at least one of the plurality of vertices through the texture map after obtaining the texture map.

The bake unit 503 is specifically configured to render the simulation model according to the texture coordinate value corresponding to the at least one vertex in the simulation model and the shadow map to obtain a try-on model.

In some implementations, the acquiring unit 501 is specifically configured to sample the shadow map according to a texture coordinate value corresponding to at least one vertex in the simulation model to obtain a sampling result; and perform shadow rendering on the simulation model according to the sampling result to obtain a try-on model.

In some implementations, the acquiring unit 501 is specifically configured to perform texture unwrapping on the simulation model according to a preset unwrapping rule to obtain a texture map, where the preset unwrapping rule refers to ensuring that a topological form in the texture map is kept consistent with a topological form in the simulation model without disrupting the vertices and connection lines in the simulation model.

In some implementations, if the try-on object is stationary relative to the target part, the shadow corresponding to the try-on object is pre-generated; and if the try-on object moves relative to the target part, the shadow corresponding to the try-on object is drawn based on an initial shadow acquired by the camera device.

In some implementations, a position and orientation of the camera device satisfy the following conditions: when the try-on object moves towards the target part, the shadow of the try-on object conforms to a relationship of being smaller at a distance and larger closer.

In some implementations, the bake unit 503 is specifically configured to perform Gaussian blur processing on the shadow to obtain a processed shadow; and bake the processed shadow onto the UV map to obtain a shadow map.

In some implementations, the apparatus further includes a rendering unit.

The rendering unit is configured to perform rendering on a target part of a user according to the try-on model when the user uses the try-on object.

In some implementations, the rendering unit is specifically configured to perform rendering on the target part of the user according to the try-on model and the processed simulation model if the try-on object encircles the target part, where the processed simulation model is opaque and is used to obscure a partial area of the try-on object.

In some implementations, the apparatus further includes a processing unit.

The processing unit is configured to acquire a grayscale map corresponding to the target part; and segment, according to the grayscale map, a shadow area corresponding to the try-on model to remove an excessive shadow area in the shadow area corresponding to the try-on model, where the excessive shadow area refers to another shadow area except the shadow area corresponding to the target part within the shadow area corresponding to the try-on model.

It should be noted that for the specific implementation of each unit in this embodiment, reference may be made to the relevant descriptions in the above method embodiments. The division of units in this embodiment of the present disclosure is schematic and merely represents a logical function division, and there may be additional division methods in actual implementation. Various functional units in the embodiments of the present disclosure may be integrated into one processing unit, each of the units may exist alone physically, or two or more units may be integrated into one unit. For example, in the above embodiment, the processing unit and a sending unit may be the same unit or different units. The above-integrated unit may be implemented in the form of hardware or a software functional unit.

Reference is made to FIG. 6, which is a schematic diagram of a structure of an electronic device 600 suitable for implementing an embodiment of the present disclosure. A terminal device in this embodiment of the present disclosure may include, but is not limited to, mobile terminals such as a mobile phone, a notebook computer, a digital broadcast receiver, a personal digital assistant (PDA), a portable Android device (PAD), a portable media player (PMP), and a vehicle terminal (e.g., a vehicle navigation terminal), and fixed terminals such as a digital TV and a desktop computer. The electronic device shown in FIG. 6 is merely an example, and shall not impose any limitation on the function and scope of use of the embodiments of the present disclosure.

As shown in FIG. 6, the electronic device 600 may include a processing apparatus (e.g., a central processing unit and a graphics processing unit) 601, which may perform various suitable actions and processing according to a program stored on a read-only memory (ROM) 602 or a program loaded from a storage apparatus 608 into a random access memory (RAM) 603. The RAM 603 further stores various programs and data needed by the operation of the electronic device 600. The processing apparatus 601, the ROM 602, and the RAM 603 are connected to one another through a bus 604. An input/output (I/O) interface 605 is also connected to the bus 604.

Typically, the following apparatuses may be connected to the I/O interface 605: an input apparatus 606, including, for example, a touchscreen, a touchpad, a keyboard, a mouse, a camera, a microphone, an accelerometer, and a gyroscope; an output apparatus 607, including, for example, a liquid crystal display (LCD), a speaker, and a vibrator; the storage apparatus 608, including, for example, a magnetic tape and a hard drive; and a communication apparatus 609. The communication apparatus 609 may allow the electronic device 600 to be in wireless or wired communication with other devices for data exchange. Although FIG. 6 illustrates the electronic device 600 with various apparatuses, it should be understood that it is not necessary to implement or have all the shown apparatuses. It may be an alternative to implement or have more or fewer apparatuses.

In particular, the above process described with reference to the flowcharts according to the embodiments of the present disclosure may be implemented as a computer software program. For example, an embodiment of the present disclosure includes a computer program product, which includes a computer program carried on a non-transitory computer-readable medium, where the computer program includes program code used to perform the method shown in the flowchart. In this embodiment, the computer program may be downloaded and installed from the network through the communication apparatus 609, or installed from the storage apparatus 608, or installed from the ROM 602. The computer program, when executed by the processing apparatus 601, performs the above functions limited in the method in this embodiment of the present disclosure.

The electronic device provided in this embodiment of the present disclosure and the method provided in the above embodiment belong to the same inventive concept, and for technical details not described in detail in this embodiment, reference may be made to the above embodiment. This embodiment and the above embodiment have the same beneficial effects.

An embodiment of the present disclosure provides a computer storage medium, storing a computer program. The program, when executed by a processor, implements the method provided in the above embodiment.

It should be noted that the above computer-readable medium in the present disclosure may be either a computer-readable signal medium or a computer-readable storage medium, or any combination of the two. The computer-readable storage medium may be, for example, but is not limited to, electric, magnetic, optical, electromagnetic, infrared, or semiconductor systems, apparatuses, or devices, or any combination of the above. More specific examples of the computer-readable storage medium may include, but are not limited to: an electrical connection with one or more wires, a portable computer disk, a hard drive, a random access memory (RAM), a read-only memory (ROM), an erasable programmable read-only memory (EPROM or a flash memory), an optical fiber, a portable compact disk read-only memory (CD-ROM), an optical storage device, a magnetic storage device, or any suitable combination of the above. In the present disclosure, the computer-readable storage medium may be any tangible medium including or storing a program, and the program may be for use by or for use in combination with an instruction execution system, apparatus, or device. However, in the present disclosure, the computer-readable signal medium may include a data signal propagated in a baseband or as a part of a carrier, where the data signal carries computer-readable program code. The propagated data signal may take various forms, including but not limited to an electromagnetic signal, an optical signal, or any suitable combination of the above. The computer-readable signal medium may also be any computer-readable medium other than the computer-readable storage medium. The computer-readable signal medium may send, propagate, or transmit a program for use by or for use in combination with the instruction execution system, apparatus, or device. The program code included in the computer-readable medium may be transmitted by any suitable medium, including but not limited to a wire, an optical cable, radio frequency (RF), etc., or any suitable combination of the above.

In some implementations, a client and a server may communicate using any currently known or future-developed network protocols such as a hyper text transfer protocol (HTTP), and may also be interconnected with digital data communication in any form or medium (e.g., a communication network). Examples of the communication network include a local area network (“LAN”), a wide area network (“WAN”), an internetwork (e.g., the Internet), a peer-to-peer network (e.g., an ad hoc peer-to-peer network), and any currently known or future-developed network.

The above computer-readable medium may be included in the above electronic device; or may also separately exist without being assembled in the electronic device.

The computer-readable medium carries one or more programs. The above one or more programs, when executed by the electronic device, cause the electronic device to perform the above method.

Computer program code for performing operations of the present disclosure may be written in one or more programming languages or a combination thereof, where the above programming languages include, but are not limited to, object-oriented programming languages, such as Java, Smalltalk, and C++, and further include conventional procedural programming languages, such as “C” language or similar programming languages. The program code may be executed entirely on a user computer, partly on the user computer, as a stand-alone software package, partly on the user computer and partly on a remote computer, or entirely on the remote computer or the server. In the case of involving the remote computer, the remote computer may be connected to the user computer through any type of network, including a local area network (LAN) or a wide area network (WAN), or may be connected to an external computer (e.g., utilizing an Internet service provider for Internet connectivity).

The flowcharts and the block diagrams in the accompanying drawings illustrate the possibly implemented system architecture, functions, and operations of the system, the method, and the computer program product according to the various embodiments of the present disclosure. In this regard, each block in the flowcharts or the block diagrams may represent a module, a program segment, or a part of code, and the module, the program segment, or the part of code contains one or more executable instructions for implementing specified logical functions. It should also be noted that in some alternative implementations, the functions marked in the blocks may also occur in an order different from those marked in the accompanying drawings. For example, two blocks shown in succession may actually be performed substantially in parallel, or may sometimes be performed in a reverse order, depending on the functions involved. It should also be noted that each block in the block diagrams and/or the flowcharts, and a combination of the blocks in the block diagrams and/or the flowcharts may be implemented by using a dedicated hardware-based system that performs specified functions or operations, or may be implemented by using a combination of dedicated hardware and computer instructions.

The involved units described in the embodiments of the present disclosure may be implemented through software or hardware. The name of the unit/module does not limit the unit in certain cases.

Herein, the functions described above may be at least partially executed by one or more hardware logic components. For example, without limitation, exemplary hardware logic components that can be used include: a field-programmable gate array (FPGA), an application-specific integrated circuit (ASIC), an application-specific standard part (ASSP), a system on chip (SOC), a complex programmable logic device (CPLD), etc.

In the context of the present disclosure, a machine-readable medium may be a tangible medium that may include or store a program for use by or for use in combination with the instruction execution system, apparatus, or device. The machine-readable medium may be a machine-readable signal medium or a machine-readable storage medium. The machine-readable medium may include, but is not limited to, an electronic, magnetic, optical, electromagnetic, infrared, or semiconductor system, apparatus, or device, or any suitable combination of the above content. More specific examples of the machine-readable storage medium may include an electrical connection based on one or more wires, a portable computer disk, a hard drive, a random access memory (RAM), a read-only memory (ROM), an erasable programmable read-only memory (EPROM or a flash memory), an optical fiber, a portable compact disk read-only memory (CD-ROM), an optical storage device, a magnetic storage device, or any suitable combination of the above content.

It should be noted that the various embodiments in the specification are described in a progressive manner, highlighting the differences between each embodiment and the other embodiments. The similar or identical parts between different embodiments may be cross-referenced to each other. The system or apparatus disclosed by the embodiment corresponds to the method disclosed by the embodiment, and therefore the description is simple, and for associated parts, reference is made to part of the description of the method.

It should be understood that in the present disclosure, “at least one (item)” means one or more, and “a plurality of” means two or more. The term “and/or” is an association relationship for describing associated objects, indicating that there may be three relationships, for example, “A and/or B” may represent three situations: A exists alone, B exists alone, and both A and B exist, where A and B may be singular or plural. The character “/” generally indicates an “or” relationship between preceding and succeeding associated objects. “At least one of the following” or similar expressions thereof refer to any combination of these items, including any combination of single or plural items. For example, at least one of a, b, or c may represent: a, b, c, “a and b”, “a and c”, “b and c”, or “a, b, and c”, where a, b, and c may be single or plural.

It should be further noted that herein, relational terms such as first and second are used only to distinguish one entity or operation from another and do not necessarily require or imply any actual relationship or order between these entities or operations. In addition, the terms “comprise”, “include”, or any other variations thereof are intended to cover non-exclusive inclusions, and therefore a process, a method, an article, or a device including a series of elements not only includes those elements but also includes other elements not clearly listed, or further includes elements inherent to the process, the method, the article, or the device. In the absence of further restrictions, an element specified by the phrase “including a . . . ” does not exclude the existence of other identical elements in the process, the method, the article, or the device that includes the element.

The steps of the method or the algorithm described in combination with the embodiments disclosed herein may be implemented directly by hardware, a software module executed by the processor, or a combination of both. The software module may be arranged in the random access memory (RAM), an internal memory, the read-only memory (ROM), the erasable programmable ROM, an electrically erasable programmable ROM, a register, the hard drive, a removable disk, the CD-ROM, or any other form of storage medium known in the technical field.

Those skilled in the art can implement or use the present disclosure according to the above descriptions of the disclosed embodiments. More modifications for these embodiments are apparent to those skilled in the art, and general principles defined herein may be implemented in other embodiments without departing from the spirit or scope of the present disclosure. Therefore, the present disclosure will not be limited by these embodiments shown herein but is required to conform to the widest scope consistent with the principles and novel characteristics disclosed herein.

1. A shadow rendering method, comprising:
acquiring a simulation model corresponding to a target part, the simulation model comprising a plurality of vertices, and the target part referring to a part where a try-on object is mounted;
performing texture unwrapping on the simulation model to obtain a texture map;
acquiring a shadow corresponding to the try-on object;
baking the shadow onto the texture map to obtain a shadow map; and
rendering the simulation model according to the vertices in the simulation model and the shadow map to obtain a try-on model.

2. The method according to claim 1, wherein after obtaining the texture map, the method further comprises:
acquiring a texture coordinate value corresponding to at least one of the plurality of vertices through the texture map,
wherein rendering the simulation model according to the vertices in the simulation model and the shadow map to obtain the try-on model comprises:
rendering the simulation model according to the texture coordinate value corresponding to the at least one vertex in the simulation model and the shadow map to obtain the try-on model.

3. The method according to claim 2, wherein rendering the simulation model according to the texture coordinate value corresponding to the at least one vertex in the simulation model and the shadow map to obtain the try-on model comprises:
sampling the shadow map according to the texture coordinate value corresponding to the at least one vertex in the simulation model to obtain a sampling result; and
performing shadow rendering on the simulation model according to the sampling result to obtain the try-on model.

4. The method according to claim 1, wherein performing texture unwrapping on the simulation model to obtain the texture map comprises:
performing texture unwrapping on the simulation model according to a preset unwrapping rule to obtain the texture map, wherein the preset unwrapping rule refers to ensuring that a topological form in the texture map is kept consistent with a topological form in the simulation model without disrupting the vertices and connection lines in the simulation model.

5. The method according to claim 1, wherein in response to the try-on object being stationary relative to the target part, the shadow corresponding to the try-on object is pre-generated; and in response to the try-on object moving relative to the target part, the shadow corresponding to the try-on object is drawn based on an initial shadow acquired by a camera device.

6. The method according to claim 5, wherein a position and orientation of the camera device satisfy the following conditions: when the try-on object moves towards the target part, the shadow of the try-on object conforms to a relationship of being smaller at a distance and larger closer.

7. The method according to claim 1, wherein baking the shadow onto the texture map to obtain the shadow map comprises:
performing Gaussian blur processing on the shadow to obtain a processed shadow; and
baking the processed shadow onto the UV map to obtain the shadow map.

8. The method according to claim 1, further comprising:
performing rendering on the target part of the user according to the try-on model in response to the user using the try-on object.

9. The method according to claim 8, wherein performing rendering on the target part of the user according to the try-on model comprises:
performing rendering on the target part of the user according to the try-on model and the processed simulation model in response to the try-on object encircling the target part, wherein the processed simulation model is opaque, and the processed simulation model is used to obscure a partial area of the try-on object.

10. The method according to claim 1, further comprising:
acquiring a grayscale map corresponding to the target part; and
segmenting, according to the grayscale map, a shadow area corresponding to the try-on model to remove an excessive shadow area in the shadow area corresponding to the try-on model, wherein the excessive shadow area refers to another shadow area except the shadow area corresponding to the target part within the shadow area corresponding to the try-on model.

11. (canceled)

12. An electronic device, wherein the device comprises a processor and a memory;
the memory is configured to store instructions or a computer program; and
the processor is configured to execute the instructions or the computer program in the memory to cause the electronic device to:
acquire a simulation model corresponding to a target part, the simulation model comprising a plurality of vertices, and the target part referring to a part where a try-on object is mounted;
perform texture unwrapping on the simulation model to obtain a texture map;
acquire a shadow corresponding to the try-on object;
bake the shadow onto the texture map to obtain a shadow map; and
render the simulation model according to the vertices in the simulation model and the shadow map to obtain a try-on model.

13. A non-transitory computer-readable storage medium, having instructions stored therein, wherein the instructions, when running on a device, cause the device to:
acquire a simulation model corresponding to a target part, the simulation model comprising a plurality of vertices, and the target part referring to a part where a try-on object is mounted;
perform texture unwrapping on the simulation model to obtain a texture map;
acquire a shadow corresponding to the try-on object;
bake the shadow onto the texture map to obtain a shadow map; and
render the simulation model according to the vertices in the simulation model and the shadow map to obtain a try-on model.

14. (canceled)

15. The electronic device of claim 12, wherein after obtaining the texture map, the electronic device is caused to:
acquire a texture coordinate value corresponding to at least one of the plurality of vertices through the texture map,
wherein when rendering the simulation model according to the vertices in the simulation model and the shadow map to obtain the try-on model comprises, the electronic device is caused to:
render the simulation model according to the texture coordinate value corresponding to the at least one vertex in the simulation model and the shadow map to obtain the try-on model.

16. The electronic device of claim 15, wherein when rendering the simulation model according to the texture coordinate value corresponding to the at least one vertex in the simulation model and the shadow map to obtain the try-on model, the electronic device is caused to:
sample the shadow map according to the texture coordinate value corresponding to the at least one vertex in the simulation model to obtain a sampling result; and
perform shadow rendering on the simulation model according to the sampling result to obtain the try-on model.

17. The electronic device of claim 12, wherein when performing texture unwrapping on the simulation model to obtain the texture map, the electronic device is caused to:
perform texture unwrapping on the simulation model according to a preset unwrapping rule to obtain the texture map, wherein the preset unwrapping rule refers to ensuring that a topological form in the texture map is kept consistent with a topological form in the simulation model without disrupting the vertices and connection lines in the simulation model.

18. The electronic device of claim 12, wherein in response to the try-on object being stationary relative to the target part, the shadow corresponding to the try-on object is pre-generated; and in response to the try-on object moving relative to the target part, the shadow corresponding to the try-on object is drawn based on an initial shadow acquired by a camera device.

19. The electronic device of claim 18, wherein a position and orientation of the camera device satisfy the following conditions: when the try-on object moves towards the target part, the shadow of the try-on object conforms to a relationship of being smaller at a distance and larger closer.

20. The electronic device of claim 12, wherein when baking the shadow onto the texture map to obtain the shadow map, the electronic device is caused to:
perform Gaussian blur processing on the shadow to obtain a processed shadow; and
bake the processed shadow onto the UV map to obtain the shadow map.

21. The electronic device of claim 12, wherein the electronic device is caused to:
perform rendering on the target part of the user according to the try-on model in response to the user using the try-on object.

22. The method of claim 21, wherein when performing rendering on the target part of the user according to the try-on model, the electronic device is caused to:
perform rendering on the target part of the user according to the try-on model and the processed simulation model in response to the try-on object encircling the target part, wherein the processed simulation model is opaque, and the processed simulation model is used to obscure a partial area of the try-on object.
